(19) United States
(12) Patent Application Publication
(10) Pub. No.: US 2009/0309647 A1
(43) Pub. Date: Dec. 17, 2009

(54) High voltage tolerant pass-gate assembly for an integrated circuit

(75) Inventors: Shao-Jen Lim, Santa Clara, CA (US); Sen-Jung Wei, San Jose, CA (US)

Correspondence Address: Roeder & Broder LLP, 5560 Chelsea Avenue, La Jolla, CA, 92037, US

(73) Assignee: Integrated Device Technology, Inc.

(21) Appl. No.: 12/214,015

(22) Filed: Jun. 16, 2008

(51) Int. Cl. H03K 17/687

(52) U.S. Cl. 327/437; 327/365; 327/427

(57) ABSTRACT

A high-voltage tolerant pass-gate assembly (18) for controlling an electrical signal between a first pad (12) and a second pad (14) includes a pass-gate (24) and a first native device (26). In certain embodiments, the first native device (26) is positioned between the first pad (12) and the pass-gate (24). The first native device (26) is permanently enabled. In another embodiment, the pass-gate assembly (18) includes a second native device (28) positioned between the pass-gate (24) and the second pad (14). The second native device (28) can also be permanently enabled. Neither the first native device (26) nor the second native device (28) controls an on-off state of the pass-gate (24). The first native device (26) can have a first voltage and the pass-gate (24) can have a supply voltage that is substantially similar to the first voltage. The first native device (26) can reduce a voltage of the input signal (20) when the voltage of the input signal (20) is above a predetermined threshold voltage that is approximately equal to a supply voltage (30) of the pass-gate (24). The first native device (26) does not reduce the voltage of the input signal (20) when the input signal (20) is below the predetermined threshold voltage.

### BACKGROUND

The use of pass-gates, also known as analog gates or analog switches, is well known in the art of integrated circuitry. Typically, the pass-gate is an electronic component such as a metal-oxide-semiconductor field-effect transistor (also referred to herein as “MOSFET”), which is a type of transistor that may be constructed with complementary metal-oxide-semiconductor (also referred to herein as “CMOS”) technology. A typical CMOS device includes complementary negative metal-oxide-semiconductor (NMOS) and positive metal-oxide-semiconductor (PMOS) transistors. Pass-gates behave in a similar way to relays. The pass-gate has a control input, which can be shifted by internal circuitry to a suitable voltage for switching the pass-gate on and off, as necessary. For example, the control input can have a logic 0 that results in a relatively high resistance at the pass-gate (such as 5 megaohms or more) to turn the switch off. On the other hand, the control input can have a logic 1 that results in a relatively low resistance at the pass-gate (such as between a few ohms and a few hundred ohms) to turn the switch on.

Conventional pass-gates designed for high-voltage tolerant circuits can suffer from a threshold voltage drop which reduces the maximum passable voltage through the pass-gate. In these circumstances, the maximum passable voltage may be no greater than the power supply minus the threshold voltage for the pass-gate. A maximum passable voltage that is lower than the power supply voltage can result in decreased performance of the circuitry. Unfortunately, attempts to increase the maximum passable voltage to at or near the power supply voltage without the loss of high-voltage tolerant capabilities have been less than satisfactory.

### SUMMARY

The present invention is directed toward a high-voltage tolerant pass-gate assembly for controlling an electrical signal between a first pad and a second pad in an I/O circuit. In one embodiment, the pass-gate assembly includes a pass-gate and a first native device. The pass-gate can be positioned between the first pad and the second pad. Further, the pass-gate receives an input signal from the first pad and selectively transmits an output signal to the second pad. In certain embodiments, the first native device is positioned between the first pad and the pass-gate. The first native device receives the input signal from the first pad. In some embodiments, the first native device is permanently enabled.

In another embodiment, the pass-gate assembly also includes a second native device that is positioned between the pass-gate and the second pad. In this embodiment, the second native device can also be permanently enabled. The pass-gate can be a bilateral switch. In certain embodiments, neither the first native device nor the second native device controls an on-off state of the pass-gate. The first and second native devices can be NMOS devices. Further, the pass-gate can be a CMOS device that includes an NMOS device and a PMOS device. The NMOS device and the PMOS device cooperate with one another to turn the pass-gate on and off.

In various embodiments, the first native device has a first voltage and the pass-gate has a supply voltage that is substantially similar or identical to the first voltage. The first native device can reduce a voltage of the input signal when the voltage of the input signal is above a predetermined threshold voltage. In one embodiment, the predetermined threshold voltage is approximately equal to a supply voltage of the pass-gate. In some embodiments, the first native device does not reduce the voltage of the input signal when the input signal is below the predetermined threshold voltage.

In another embodiment, the pass-gate includes a charge pump. In this embodiment, the predetermined threshold voltage is greater than the supply voltage of the pass-gate. In yet another embodiment, the first native device is incorporated as part of an electrostatic discharge device.

The present invention is also directed toward a method for controlling an electrical signal between a first pad and a second pad in an I/O circuit.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a schematic diagram of one embodiment of a portion of a circuit including a pass-gate assembly having features of the present invention;

FIG. 2 is a graph illustrating voltage waveforms of a representative input signal and a resulting output signal following adjustment of the input signal by the embodiment of the pass-gate assembly illustrated in FIG. 1;

FIG. 3 is a schematic diagram of a portion of another embodiment of the circuit including the pass-gate assembly;

FIG. 4 is a schematic diagram of a portion of the circuit including another embodiment of the pass-gate assembly; and

FIG. 5 is a schematic diagram of a portion of the circuit including yet another embodiment of the pass-gate assembly.

### DESCRIPTION

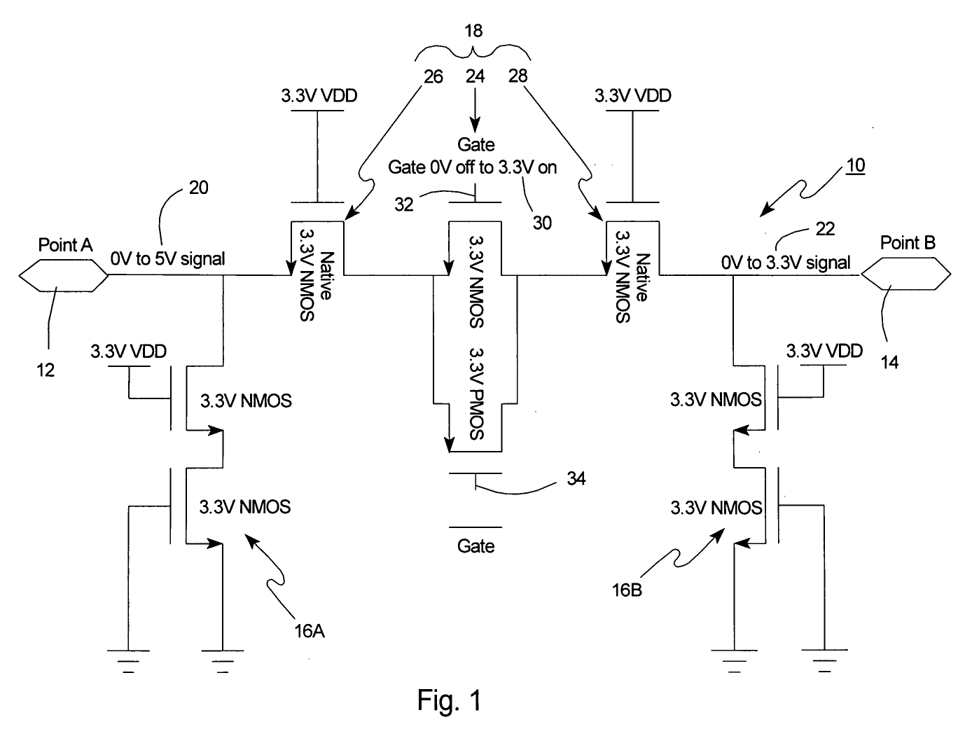

FIG. 1 is a schematic diagram of one embodiment of a portion of a circuit 10 having features of the present invention. In this embodiment, the circuit 10 includes a first pad 12, a second pad 14, one or more electrostatic discharge (ESD) devices (a first ESD device 16A and a second ESD device 16B are illustrated in FIG. 1) and a pass-gate assembly 18. In FIG. 1, the first pad 12 is illustrated as Point A, which is representative of any suitable point from which an electrical signal is transmitted and/or received in an integrated circuit. Somewhat similarly, the second pad 14 is illustrated as Point B, which is representative of any other suitable point from which an electrical signal is transmitted and/or received in an integrated circuit, and which is in electrical communication with Point A.

For ease of discussion, the electrical signal that is transmitted from the first pad 12 to the pass-gate assembly 18 will be referred to herein as an input signal 20. The electrical signal that is transmitted from the pass-gate assembly 18 to the second pad 14 will be referred to herein as an output signal 22. It is recognized, however, that either pad 12, 14 can be the first pad 12 or the second pad 14. Therefore, the input signal 20 and the output signal 22 illustrated in FIG. 1 can likewise be reversed. In one embodiment, the input signal 20 from the first pad 12 to the pass-gate assembly 18 can be an analog signal in the approximate voltage range of 0V to 5V. In alternative embodiments, the input signal 20 can have another suitable voltage range.

The ESD devices 16A, 16B inhibit or prevent electrostatic discharge events within the circuit 10. It is generally known that an ESD event can cause catastrophic damage to many types of circuits, immediately rendering the circuit inoperable. Alternatively, an ESD event can cause latent damage so that the circuit 10 appears to function properly for the short term, but eventually fails at some point in the future. The presence of the ESD devices 16A, 16B in this circuit 10 allow the circuit 10 to function properly for a longer period of time.

The type(s) of ESD devices 16A, 16B can be varied depending upon the design requirements of the circuit 10. In the embodiment illustrated in FIG. 1, the ESD devices 16A, 16B are substantially identical. However, in an alternative embodiment, the ESD devices 16A, 16B can be different. FIG. 1 illustrates one representative type of ESD device (used for both 16A, 16B). It is understood that other types and/or designs of ESD devices (not shown) can be used in the circuit 10 without deviating from the scope and intent of the present invention.

In the embodiment illustrated in FIG. 1, the first ESD device 16A is positioned along the circuit 10 between the first pad 12 and the pass-gate assembly 18. The second ESD device 16B is positioned along the circuit 10 between the pass-gate assembly 18 and the second pad 14. It is recognized that in alternative embodiments, the positioning of the ESD devices 16A, 16B can be modified from that shown in FIG. 1 to best suit the design requirements of the circuit 10. Further, in another embodiment (not shown), one or both of the ESD devices 16A, 16B can be omitted from the circuit 10.

In the embodiment illustrated in FIG. 1, the pass-gate assembly 18 functions as an analog switch that receives the input signal 20 from the first pad 12 and selectively transmits the output signal 22 to the second pad 14. In this embodiment, the pass-gate assembly 18 is bidirectional. Stated another way, in the embodiment illustrated in FIG. 1, an electrical signal can flow through the pass-gate assembly 18 in either direction, i.e. from the first pad 12 toward the second pad 14, or vice versa.

The design of the pass-gate assembly 18 can be varied depending upon the design requirements of the circuit 10. In the embodiment illustrated in FIG. 1, the pass-gate assembly 18 includes a pass-gate 24, a first native device 26 and a second native device 28. In one embodiment, the pass-gate 24 is positioned between the first native device 26 and the second native device 28.

In certain embodiments, the pass-gate 24 is a transistor assembly that is constructed with CMOS technology. In the embodiment illustrated in FIG. 1, the pass-gate 24 includes a parallel combination of a 3.3V NMOS transistor and a 3.3V PMOS transistor, as illustrated in FIG. 1. The pass-gate 24 is supplied with a supply voltage 30, which in the embodiment illustrated in FIG. 1, is 3.3V. The supply voltage 30 includes an input 32 at the gate of the NMOS transistor and an input 34 at the gate of the PMOS transistor. The input 32 to the NMOS transistor is complementary to the input 34 to the PMOS transistor. It is recognized that the voltages of the transistors in the pass-gate 24 can vary from those shown and described relative to FIG. 1. For example, the voltages can be higher or lower than 3.3V, depending on the design requirements of the circuit 10 and/or the pass-gate assembly 18. In an alternative embodiment, the pass-gate 24 can be constructed with technology other than CMOS technology. Additionally, it is noted that the voltages of the various structures and devices in FIG. 1 are representative of one possible embodiment of the circuit 10, and are not intended to be all-inclusive of the voltages that can be utilized with the present invention.

As used herein, the term “native device” refers to transistors that are formed in a doped semiconductor region (not shown), a channel (not shown) of which has not undergone any surface enhancement or surface depletion. The channel is therefore formed directly on the surface of the doped semiconductor region without the performance of an ion implantation or diffusion after the formation of a well. The native transistor has a lower threshold voltage because it must rely on the intrinsic background or body of the transistor to set the threshold voltage. The typical native transistor threshold voltage can range from 0.1V to 0.3V, although it is recognized that the threshold voltage can alternatively fall outside this range.

The design of the native device 26, 28 can vary. In the embodiments illustrated in the Figures, the native devices 26, 28 are NMOS native devices. In an alternative embodiment (not shown), the native devices can be PMOS native devices. In the embodiment illustrated in FIG. 1, the native devices 26, 28 are permanently enabled, e.g., these are “always on” native devices 26, 28. Because the native devices 26, 28 are permanently enabled, they do not participate in controlling the on/off status of the pass-gate 24.

The first native device 26 selectively modifies the voltage of the input signal 20 from the first pad 12 to the pass-gate 24. The first native device 26 receives the input signal 20 from the first pad 12. As illustrated in FIG. 1, assuming the voltage of the input signal 20 is within the range of 0V to 5V, the first native device 26 can have various effects on the input signal 20. In this embodiment, if the voltage of the input signal 20 is 0V to 3.3V, the first native device 26 will not modify or adjust the voltage of the input signal 20. Thus, in this scenario, the input signal 20 will be transmitted to the pass-gate 24 at substantially the same voltage. For example, if the voltage of the input signal 20 is 3.0V, the first native device 26 will not change this voltage, and a 3.0V signal will be transmitted to the pass-gate 24. Assuming the pass-gate 24 is in an “on” state, a 3.0V output signal 22 will pass through the pass-gate and will be transmitted to the second pad 14. During current flow in the direction from the first pad 12 to the second pad 14, the second native device 28 has no effect on the output signal 22.

Further, in this non-exclusive embodiment, if the input signal 20 is greater than a predetermined upper threshold voltage, such as 3.3V (e.g., greater than the 3.3V supply voltage 30 to the pass-gate 24), the first native device 26 will reduce the voltage of the input signal to approximately 3.3V. Thus, in certain embodiments, the voltage of the native devices 26, 28 is coordinated with the upper threshold voltage, e.g., the supply voltage 30. For example, if the voltage of the input signal 20 is 5.0V, which exceeds the upper threshold voltage of 3.3V, the first native device 26 will reduce this voltage to 3.3V, and this reduced voltage input signal 20 will be transmitted to the pass-gate 24. Assuming the pass-gate 24 is in an “on” state, approximately a 3.3V output signal 22 will be transmitted to the second pad 14. In certain embodiments, the upper threshold voltage is approximately equal or is identical to the supply voltage 30 to the pass-gate 24.

In another embodiment (not shown), the pass-gate 24 can include a charge pump that can increase the original supply voltage 30 to the pass-gate, thereby increasing the upper threshold voltage. In other words, in this embodiment, the first native device 26 can have a voltage that exceeds the original supply voltage 30 to the pass-gate 24, provided the original supply voltage 30 can be increased accordingly via utilization of the charge pump. For example, with a signal being transmitted in a direction from the first pad 12 to the second pad 14, the first native device 26 can have a voltage of 5.0V even if the supply voltage 30 to the pass-gate 24 is less than 5.0V, provided the charge pump can increase the supply voltage to the pass-gate 24 to at least 5.0V.

With the designs provided herein, the first native device 26 inhibits a voltage drop between the first pad 12 and the pass-gate 24. As a result, a voltage of the input signal 20 of at least 3.3V more closely approximates the supply voltage 30 to the pass-gate 24 (in this embodiment, 3.3V), which allows an increased voltage of the output signal (little or no threshold voltage drop) to be transmitted to the second pad 14, without loss of high-voltage tolerant capabilities of the circuit 10.

As provided above, in this embodiment, the pass-gate 24 is bilateral. Therefore, somewhat similarly, the above description is applicable for an input signal 20 that is transmitted from the second pad 14 toward the first pad 12. However, in this direction, the second native device 28 selectively adjusts or modifies the voltage of the input signal 20 from the second pad 14 to the pass-gate 24 in the manner previously described for ultimate transmission of the output signal 22 to the first pad 12. Further, in this direction, the first native device 26 has no impact on the output signal 22 from the pass-gate 24 to the first pad 12.

In certain embodiments, the first native device 26 is positioned adjacent to the first pad 12. As used in this context, the term “adjacent” means that there are no intervening structures positioned between the first native device 26 and the first pad 12, such as other gates (including NAND gates or NOR gates), for example. Instead, the first native device 26 is the first structure that is encountered by the input signal 20 from the first pad 12, other than the ESD device 16A, which does not effectively alter the input signal 20, if at all. Somewhat similarly, the second native device 28 is positioned adjacent to the second pad 14. In other words, the second native device 28 is the first structure that is encountered by the input signal 20 coming from the second pad 14, other than the ESD device 16B, which does not effectively alter the input signal 20, if at all.

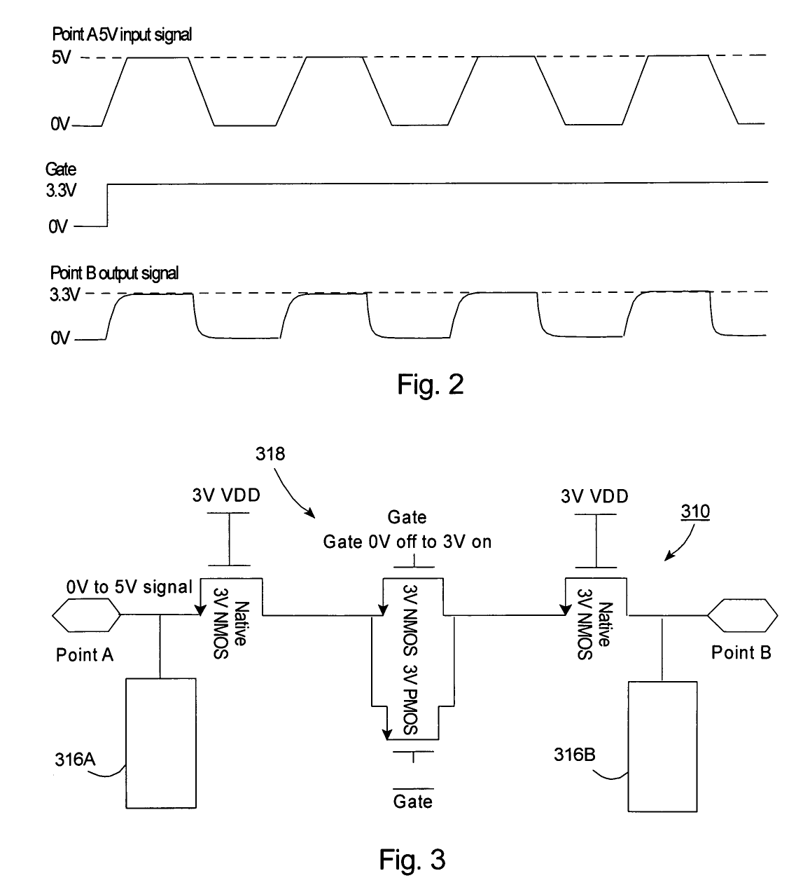

FIG. 2 is a graph illustrating voltage waveforms of a representative input signal and a resulting output signal following adjustment of the input signal by the embodiment of the pass-gate assembly illustrated in FIG. 1. The uppermost portion of the graph illustrates the waveform of a typical 5V input signal. The middle portion of the graph represents the pass-gate in an “on” state. The lowermost portion of the graph illustrates the waveform of the output signal following adjustment of the input signal by the first native device of the pass-gate assembly. As illustrated in FIG. 2, the waveform of the output signal more closely approximates the 3.3V supply voltage to the pass-gate. Stated another way, the pass-gate assembly provided herein inhibits a threshold voltage drop following transmission of the input signal through the pass-gate.

FIG. 3 is a schematic diagram of a portion of another embodiment of a circuit 310 including the pass-gate assembly 318. In this embodiment, the first ESD device 316A and the second ESD device 316B are illustrated more generally by boxes because it is recognized that the ESD devices 316A, 316B can be varied from the more specific ESD devices 16A, 16B illustrated in FIG. 1.

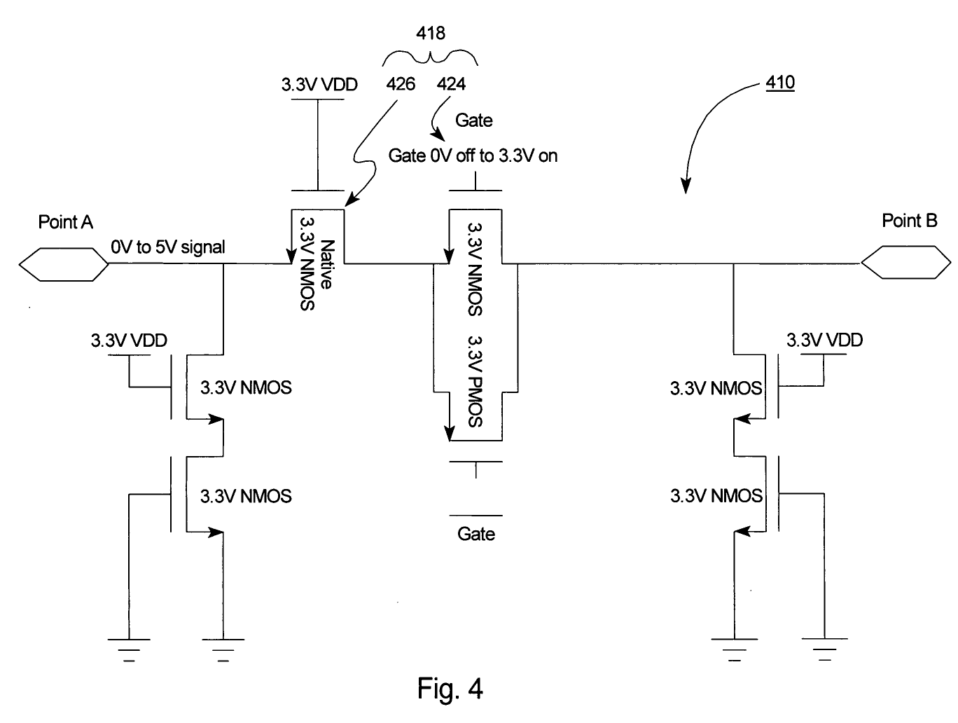

FIG. 4 is a schematic diagram of a portion of a circuit 410 including another embodiment of a pass-gate assembly 418. In this embodiment, the pass-gate assembly 418 includes a pass-gate 424 and a first native device 426. Thus, in this embodiment, the second native device 28 (illustrated in FIG. 1, for example) is omitted.

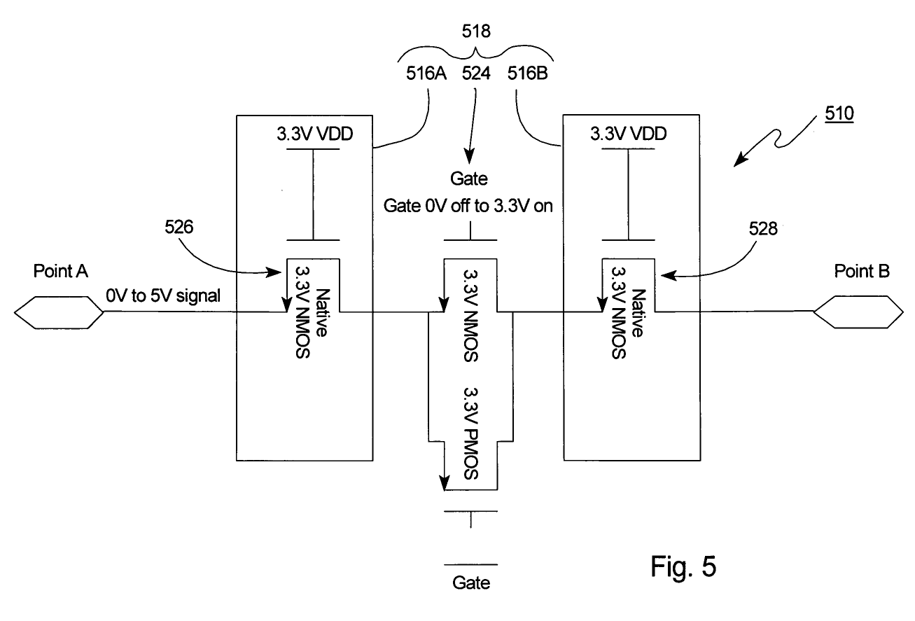

FIG. 5 is a schematic diagram of a portion of a circuit 510 including yet another embodiment of a pass-gate assembly 518. In this embodiment, the pass-gate assembly 518 includes a pass-gate 524, a first ESD device 516A and a second ESD device 516B. In the embodiment illustrated in FIG. 5, the first ESD device 516A includes a first native device 526, and the second ESD device 516B includes a second native device 528. By including the native devices 526, 528 as part of the ESD devices 516A, 516B, respectively, space can be conserved within the circuit 510.

The specific construction of the ESD devices 516A, 516B can vary. For example, although not specifically illustrated in FIG. 5, in one embodiment, the first ESD device 516A can include a cascade of diodes with a first anode connected to the first pad 512 and a last cathode connected to VDD. Alternatively, or in addition, the second ESD device 516B can include a cascade of diodes with a first anode connected to the second pad 514 and a last cathode connected to VDD.

While the particular circuit 10 and pass-gate assembly 18 as herein shown and disclosed in detail are fully capable of obtaining the objects and providing the advantages herein before stated, it is to be understood that they are merely illustrative of one or more embodiments and that no limitations are intended to the details of construction or design herein shown other than as described in the appended claims.

What is claimed is:

1. A high-voltage tolerant pass-gate assembly for controlling an electrical signal between a first pad and a second pad in an I/O circuit, the pass-gate assembly comprising:
a pass-gate positioned between the first pad and the second pad, the pass-gate receiving an input signal and selectively transmitting an output signal to the second pad; and
a first native device positioned between the first pad and the pass-gate, the first native device receiving the input signal from the first pad, the first native device being permanently enabled.

2. The pass-gate assembly of claim 1 further comprising a second native device that is positioned between the pass-gate and the second pad.

3. The pass-gate assembly of claim 2 wherein the second native device is permanently enabled.

4. The pass-gate assembly of claim 2 wherein the pass-gate is a bilateral switch.

5. The pass-gate assembly of claim 2 wherein neither the first native device nor the second native device controls an on-off state of the pass-gate.

6. The pass-gate assembly of claim 1 wherein the first native device is an NMOS device.

7. The pass-gate assembly of claim 1 wherein the first native device does not control an on-off state of the pass-gate.

8. The pass-gate assembly of claim 1 wherein the pass-gate is a CMOS device that includes an NMOS device and a PMOS device.

9. The pass-gate assembly of claim 8 wherein the NMOS device and the PMOS device cooperate with one another to turn the pass-gate on and off.

10. The pass-gate assembly of claim 1 wherein the first native device has a first voltage and the pass-gate has a supply voltage that is substantially similar to the first voltage.

11. The pass-gate assembly of claim 1 wherein the first native device has a first voltage and the pass-gate has a supply voltage that is identical to the first voltage.

12. The pass-gate assembly of claim 1 wherein the first native device reduces a voltage of the input signal when the voltage of the input signal is above a predetermined threshold voltage.

13. The pass-gate assembly of claim 12 wherein the predetermined threshold voltage is approximately equal to a supply voltage of the pass-gate.

14. The pass-gate assembly of claim 12 wherein the first native device does not reduce the voltage of the input signal when the input signal is below the predetermined threshold voltage.

15. The pass-gate assembly of claim 12 wherein the pass-gate includes a charge pump, and wherein the predetermined threshold voltage is greater than the supply voltage of the pass-gate.

16. The pass-gate assembly of claim 1 wherein the first native device is incorporated as part of an electrostatic discharge device.

17. A method for controlling an electrical signal between a first pad and a second pad in an I/O circuit, the method comprising the steps of:
positioning a pass-gate between the first pad and the second pad so that the pass-gate receives an input signal from the first pad and selectively passes an output signal to the second pad; and
selectively adjusting a voltage of the input signal with a permanently enabled first native device that is positioned between the first pad and the pass-gate.

18. The method of claim 17 further comprising the step of positioning a second native device between the pass-gate and the second pad.

19. The method of claim 18 wherein the step of positioning the second native device includes permanently enabling the second native device.

20. The method of claim 18 wherein the pass-gate is a bilateral switch.

21. The method of claim 18 wherein neither the first native device nor the second native device controls an on-off state of the pass-gate.

22. The method of claim 17 wherein the step of selectively adjusting a voltage includes the first native device being an NMOS device.

23. The method of claim 17 wherein the first native device does not control an on-off state of the pass-gate.

24. The method of claim 17 wherein the step of positioning a pass-gate includes the pass-gate including a CMOS device having an NMOS device and a PMOS device.

25. The method of claim 24 wherein the step of positioning a pass-gate includes the NMOS device and the PMOS device cooperating with one another to turn the pass-gate on and off.

26. The method of claim 17 wherein the step of positioning includes the pass-gate has a supply voltage, and the step of selectively adjusting includes the first native device having a first voltage and that is substantially similar to the supply voltage.

27. The method of claim 17 wherein the step of selectively adjusting includes the first native device reducing a voltage of the input signal when the voltage of the input signal is above a predetermined threshold voltage.

28. The method of claim 27 wherein the predetermined threshold voltage is approximately equal to a supply voltage of the pass-gate.

29. The method of claim 27 wherein the step of selectively adjusting includes the first native device not reducing the voltage of the input signal when the input signal is below the predetermined threshold voltage.

30. The method of claim 27 wherein the step of positioning includes the pass-gate having a charge pump, and wherein the predetermined threshold voltage is greater than the supply voltage of the pass-gate.

31. The method of claim 17 wherein the step of selectively adjusting includes the first native device being incorporated as part of an electrostatic discharge device.

32. A high-voltage tolerant pass-gate assembly for controlling an electrical signal between a first pad and a second pad in an I/O circuit, the pass-gate assembly comprising:
a pass-gate positioned between the first pad and the second pad, the pass-gate receiving an input signal and selectively transmitting an output signal to the second pad, the pass-gate alternately having an on status or an off status;
a first native device positioned between the first pad and the pass-gate, the first native device receiving the input signal from the first pad, the first native device being permanently enabled, the first native device being adapted to (i) reduce a voltage of the input signal when the voltage of the input signal is above a predetermined threshold voltage, and (ii) not reduce the voltage of the input signal when the voltage of the input signal is below the predetermined threshold voltage; and
a second native device that is positioned between the pass-gate and the second pad, the second native device being permanently enabled;
wherein neither the first native device nor the second native device controls the on status or the off status of the pass-gate.

33. The pass-gate assembly of claim 32 wherein the predetermined threshold voltage is approximately equal to a supply voltage of the pass-gate.

34. The pass-gate assembly of claim 32 wherein the first native device is incorporated as part of an electrostatic discharge device.
